(19) United States
(12) Patent Application Publication
(10) Pub. No.: US 2026/0090048 A1
(43) Pub. Date: Mar. 26, 2026

(54) SEMICONDUCTOR DEVICE AND METHOD FOR MANUFACTURING SEMICONDUCTOR DEVICE

(71) Applicant: Mitsubishi Electric Corporation, Tokyo (JP)

(72) Inventors: Naoki YOSHIOKA, Tokyo (JP); Daisuke TSUNAMI, Tokyo (JP)

(73) Assignee: Mitsubishi Electric Corporation, Tokyo (JP)

(21) Appl. No.: 19/112,132

(22) PCT Filed: Feb. 14, 2023
(86) PCT No.: PCT/JP2023/005058

§ 371 Date: Mar. 14, 2025

(51) Int. Cl. H10D 62/834; H10D 30/47; H10D 62/832

(52) U.S. Cl. CPC H10D 62/834; H10D 30/471; H10D 62/8325

(57) ABSTRACT

A SiC substrate (10) is doped with vanadium. A high electron mobility transistor (20) is provided on the SiC substrate (10). The SiC substrate (10) includes a first substrate (1) and a second substrate (2) provided on the first substrate (1). Vanadium concentration of the first substrate (1) is 1×10¹⁸ cm⁻³ or more. Vanadium concentration of the second substrate (2) at an interface between the second substrate (2) and the high electron mobility transistor (20) is 1×10¹⁷ cm⁻³ or less.

### FIELD

The present disclosure relates to a semiconductor device and a method for manufacturing the semiconductor device.

### BACKGROUND

In a high electron mobility transistor (HEMT), a SiC substrate that is doped with a dopant such as vanadium and introduces a defect providing a semi-insulating property is used (for example, see PTL 1).

### CITATION LIST

### Patent Literature

[PTL 1] JP 2022-519825 A

### SUMMARY OF THE INVENTION

### Problems to be Solved by the Invention

In an HEMT manufacturing process, in a state where a substrate thickness is large after a semiconductor layer is formed on a substrate, a warpage amount of the substrate is small. However, when the substrate is thinned, the warpage amount of the substrate is increased to an inappropriate level. An elastic modulus is improved by doping a SiC substrate with vanadium. This makes it possible to reduce the warpage amount of the substrate. However, there is an issue that increase in vanadium concentration causes current collapse.

The present disclosure is made to solve the above-described issues, and an object of the present disclosure is to provide a semiconductor device that can suppress current collapse while reducing a warpage amount of a substrate, and a method for manufacturing the semiconductor device.

### Solution to Problem

A semiconductor device according to the present disclosure includes a SiC substrate doped with vanadium; and a high electron mobility transistor provided on the SiC substrate, wherein the SiC substrate includes a first substrate and a second substrate provided on the first substrate, vanadium concentration of the first substrate is 1×10¹⁸ cm⁻³ or more, and vanadium concentration of the second substrate at an interface between the second substrate and the high electron mobility transistor is 1×10¹⁷ cm⁻³ or less.

### Advantageous Effects of Invention

In the present disclosure, the vanadium concentration of the second substrate at an interface between the second substrate and the high electron mobility transistor is set to 1×10¹⁷ cm⁻³ or less. This makes it possible to suppress current collapse. Although the vanadium concentration of the second substrate on the high electron mobility transistor side is reduced, the vanadium concentration of the first substrate is set to 1×10¹⁸ cm⁻³ or more, which makes it possible to reduce the warpage amount of the substrate.

### BRIEF DESCRIPTION OF THE DRAWINGS

FIG. 1 is a cross-sectional view illustrating a semiconductor device according to Embodiment 1.

FIG. 2 is a diagram illustrating vanadium concentration of the SiC substrate according to Embodiment 1.

FIG. 3 is a diagram illustrating vanadium concentration of a SiC substrate according to Embodiment 2.

FIG. 4 is a diagram illustrating comparison of the substrate warpage and the current collapse between Embodiment 1 and Embodiment 2.

### DESCRIPTION OF EMBODIMENTS

A semiconductor device and a method for manufacturing the semiconductor device according to the embodiments of the present disclosure will be described with reference to the drawings. The same components will be denoted by the same symbols, and the repeated description thereof may be omitted.

### Embodiment 1

FIG. 1 is a cross-sectional view illustrating a semiconductor device according to Embodiment 1. A SiC substrate 10 is doped with vanadium. A GaN-HEMT 20 as a high electron mobility transistor is provided on the SiC substrate 10. The SiC substrate 10 includes a first substrate 1 and a second substrate 2 provided on the first substrate 1.

The GaN-HEMT 20 includes a nucleation layer 3, a high resistance layer 4, a channel layer 5, and an electron supply layer 6 that are stacked in order on the second substrate 2. The nucleation layer 3 is made of Alₓ1Ga_{y1}In_{1-x1-y1}N (0≤x1, y1≤1), and has a thickness of 5 nm to 100 nm. The high resistance layer 4 is made of Alₓ₂Ga_{y2}In_{1-x2-y2}N (0≤x2, y2≤1), and has a thickness of 100 nm to 1000 nm. The high resistance layer 4 is added with Fe, C, Mn, and the like. Impurity concentration of the high resistance layer 4 is 1E+17 cm⁻³ to 1E+19 cm⁻³. The channel layer 5 is made of Alₓ₃Ga_{y3}In_{1-x3-y3}N (0≤x3, y3≤1), and has a thickness of 100 nm to 1000 nm. The electron supply layer 6 is made of Alₓ₄Ga_{y4}In_{1_x4-y4}N (0≤x4, y4≤1), and has a thickness of 1 nm to 50 nm. A gate electrode 7, a source electrode 8, and a drain electrode 9 are provided on the electron supply layer 6.

Subsequently, a method for manufacturing the semiconductor device according to Embodiment 1 is described. The first substrate 1 is manufactured by a sublimation method. Thereafter, the second substrate 2 is manufactured on the first substrate 1 by a CVD method. In the CVD method, SiCl₄, SiH₄, SiH₃Cl, SiH₂Cl₂, SiHCl₃, Si₂H₆, Si₃H₈, SiH₃(CH₃), SiCl₃(CH₃), or the like is used as a silicon source, CH₄, C₃H₈, or the like is used as a carbon source, VCl₃, V[N(CH₃)₂]₄, or the like is used as a vanadium source, and N₂, H₂, Ar, He, or the like is used as carrier gas. A pressure is set to 5 kPa to 100 kPa, and a temperature is set to 1000° C. to 1800° C.

Thereafter, the nucleation layer 3, the channel layer 5, and the electron supply layer 6 are stacked in order on the second substrate 2, and the gate electrode 7, the source electrode 8, and the drain electrode 9 are formed on the electron supply layer 6 to form the GaN-HEMT 20. After the GaN-HEMT 20 is formed, the first substrate 1 in a wafer state is thinned by being ground/polished from a rear surface. Thereafter, the wafer is divided into chips.

A thickness of the first substrate 1 before the thinning is 300 μm to 500 μm, and the thickness of the first substrate 1 after the thinning is 10 μm to 50 μm. A thickness of the second substrate 2 is 10 μm to 50 μm. Therefore, a total thickness of the SiC substrate 10 before the thinning is 310 μm to 550 μm. If the total thickness is less than the thickness, the SiC substrate 10 is easily warped during the process, whereas if the total thickness is greater than the thickness, its cost is increased. The total thickness of the SiC substrate 10 after the thinning is 20 μm to 100 μm.

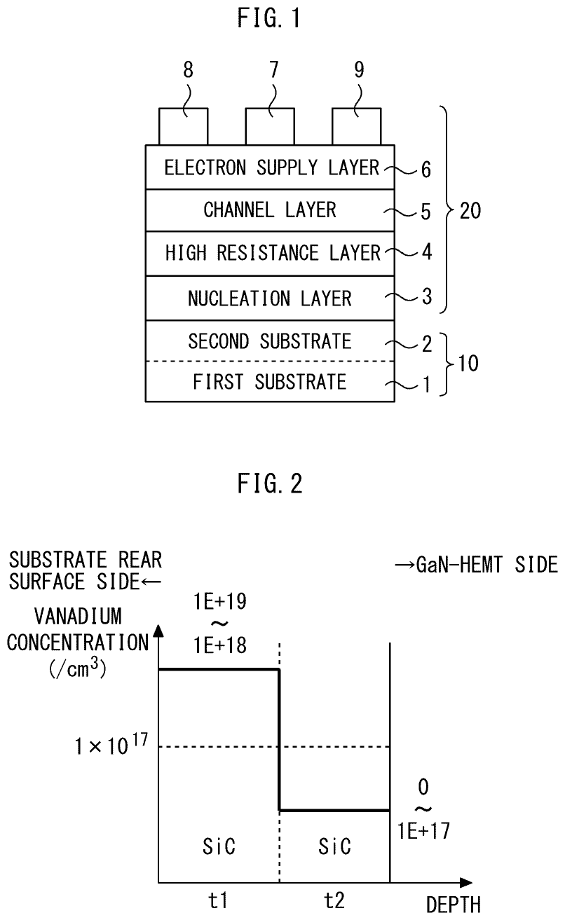

FIG. 2 is a diagram illustrating vanadium concentration of the SiC substrate according to Embodiment 1. Vanadium concentration of the first substrate 1 is fixed to 1×10¹⁸ cm⁻³ to 1×10¹⁹ cm⁻³. On the other hand, vanadium concentration of the second substrate 2 is fixed to 0 cm⁻³ to 1×10¹⁷ cm⁻³. As described above, although the vanadium concentration of the SiC substrate 10 is varied in a thickness direction, average vanadium concentration of the SiC substrate 10 is 1×10¹⁷ cm⁻³ to 1×10¹⁹ cm⁻³.

A warpage amount h of a wafer in which a semiconductor layer is epitaxially grown on a substrate is represented by the following expression.

$$h ≅ \frac{3}{4} \frac{{t}_{epi} {E}_{epi}}{{t}_{sub}^{2} {E}_{sub}} {R}^{2} {ε}_{epi} \qquad [ Math . 1 ]$$

where tsub is a thickness of the substrate, tepi is a thickness of the semiconductor layer, Esub is an elastic modulus of the substrate, Eepi is an elastic modulus of the semiconductor layer, R is a wafer diameter, and Eepi is in-plane strain. It is found from the expression that the warpage amount h can be reduced by increasing the elastic modulus Esub of the substrate.

Bonding strength of vanadium and carbon is higher than bonding strength of silicon and carbon. Therefore, the elastic modulus of the SiC substrate 10 is increased by doping with vanadium. Table 1 illustrates theoretical calculation results of the vanadium concentration and the warpage amount of the substrate of the semiconductor device according to Embodiment 1 after the thinning. It is found that the warpage amount of the substrate is reduced by setting the vanadium concentration of the first substrate 1 to 1×10¹⁸ cm⁻³ or more.

TABLE 1

| Vanadium | Vanadium | | |
|---|---|---|---|
| concentration of | concentration of | | Warpage amount |
| first substrate | second substrate | t1/t2 | (standardized) |
| 0 | 0 | 1 | 1 |
| 1E+18 | 5E+16 | 1 | 0.87 |
| 3E+18 | 5E+16 | 1 | 0.69 |

As described above, in the present embodiment, the vanadium concentration of the second substrate 2 at an interface between the second substrate 2 and the GaN-HEMT 20 is set to 1×10¹⁷ cm⁻³ or less. This makes it possible to suppress current collapse. By setting the vanadium concentration of the second substrate 2 at the interface to 1×10¹⁶ cm⁻³ or less, the current collapse can be further suppressed.

Although the vanadium concentration of the second substrate 2 on the GaN-HEMT 20 side is reduced, the vanadium concentration of the first substrate 1 is set to 1×10¹⁸ cm⁻³ or more, which makes it possible to realize the average vanadium concentration of the entire SiC substrate 10 of 1×10¹⁷ cm⁻³ to 1×10¹⁹ cm⁻³. As a result, the warpage amount of the substrate can be reduced.

When the second substrate 2 on the GaN-HEMT 20 side is manufactured by the CVD method, it is possible to suppress defects such as threading dislocation in the second substrate 2 and an epitaxial layer of the GaN-HEMT 20 provided on the second substrate 2.

### Embodiment 2

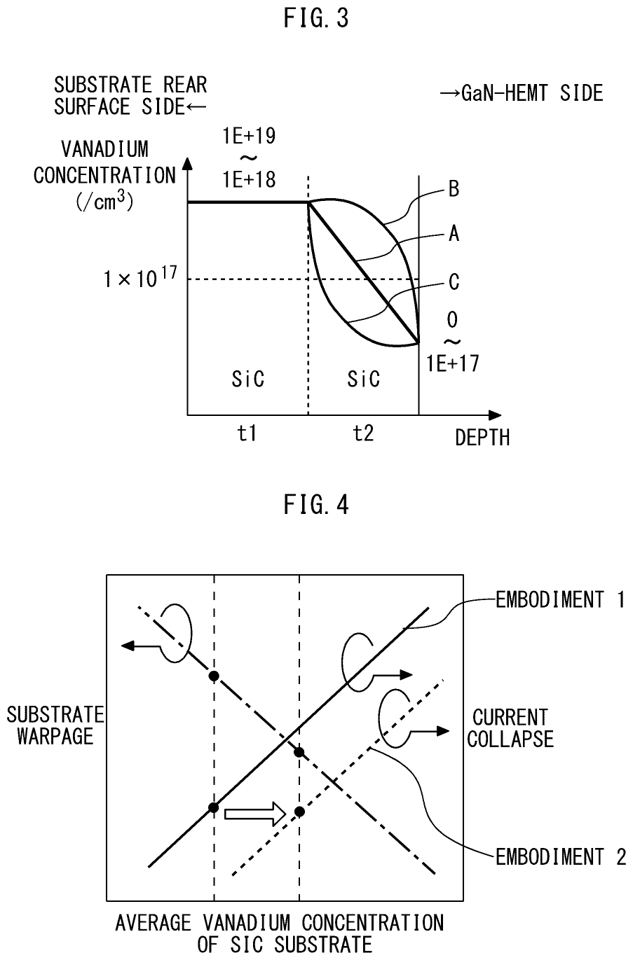

A semiconductor device according to Embodiment 2 is different in variation of the vanadium concentration of the SiC substrate 10 in the thickness direction from the semiconductor device according to Embodiment 1. FIG. 3 is a diagram illustrating vanadium concentration of a SiC substrate according to Embodiment 2. The vanadium concentration of the first substrate 1 is fixed to 1×10¹⁸ cm⁻³ to 1×10¹⁹ cm⁻³, as in Embodiment 1. On the other hand, the vanadium concentration of the second substrate 2 is equivalent to the vanadium concentration of the first substrate 1 at the interface between the first substrate 1 and the second substrate 2, and is continuously reduced toward the GaN-HEMT 20. Variation of the vanadium concentration of the second substrate 2 is not limited to linear variation like a pattern A, and may be curved variation like a pattern B or C. In the pattern B, the substrate warpage is improved as compared with the pattern A. In the pattern C, the current collapse is improved as compared with the pattern A. Note that the second substrate 2 is manufactured by the CVD method while raw material gas of vanadium is reduced.

Table 2 illustrates theoretical calculation results of the vanadium concentration and the warpage amount of the substrate of the semiconductor device according to Embodiment 2 after the thinning.

TABLE 2

| | Vanadium | | |
|---|---|---|---|
| Vanadium | concentration of | | |
| concentration of | second substrate | | Warpage amount |
| first substrate | (average) | t1/t2 | (standardized) |
| 0 | 0 | 1 | 1 |
| 1E+18 | 1E+17 | 1 | 0.86 |
| 3E+18 | 1E+17 | 1 | 0.69 |

As in Embodiment 1, the vanadium concentration of the second substrate 2 at the interface between the second substrate 2 and the GaN-HEMT 20 is set to 1×10¹⁷ cm⁻³ or less. This makes it possible to suppress current collapse. In addition, the vanadium concentration of the first substrate 1 is set to 1×10¹⁸ cm⁻³ or more, which makes it possible to realize the average vanadium concentration of the SiC substrate 10 of 1×10¹⁷ cm⁻³ to 1×10¹⁹ cm⁻³. As a result, the warpage amount of the substrate can be reduced.

FIG. 4 is a diagram illustrating comparison of the substrate warpage and the current collapse between Embodiment 1 and Embodiment 2. To obtain the same current collapse, the average vanadium concentration of the SiC substrate is larger in Embodiment 2 than in Embodiment 1. Therefore, the substrate warpage can be further reduced in Embodiment 2.

Further, in Embodiment 2, since the vanadium concentration of the second substrate 2 is continuously varied, defects in the second substrate 2 and the epitaxial layer of the GaN-HEMT 20 can be reduced as compared with Embodiment 1.

A polytype of the SiC substrate commonly used is 4H-SiC or 6H-SiC. Therefore, in consideration of its cost, the polytype of the first substrate 1 is set to 4H-SiC or 6H-SiC in Embodiments 1 and 2. On the other hand, the polytype of the second substrate 2 on the GaN-HEMT side is preferably set to 3C-SiC that is high in thermal conductivity. This makes it possible to improve heat dissipation. The polytype of 3C-SiC can be manufactured by changing a CVD condition, for example, by adjusting a flow rate of the carrier gas or reducing a growth temperature.

### REFERENCE SIGNS LIST

1 first substrate; 2 second substrate; 3 nucleation layer; 4 high resistance layer; 5 channel layer; 6 electron supply layer; 7 gate electrode; 8 source electrode; 9 drain electrode; 10 SiC substrate; 20 GaN-HEMT (high electron mobility transistor)

1. A semiconductor device comprising:
a SiC substrate doped with vanadium; and
a high electron mobility transistor provided on the SiC substrate,
wherein the SiC substrate includes a first substrate and a second substrate provided on the first substrate,
vanadium concentration of the first substrate is 1×10¹⁸ cm⁻³ or more, and
vanadium concentration of the second substrate at an interface between the second substrate and the high electron mobility transistor is 1×10¹⁷ cm⁻³ or less.

2. The semiconductor device according to claim 1, wherein the vanadium concentration of the second substrate at the interface between the second substrate and the high electron mobility transistor is 1×10¹⁶ cm⁻³ or less.

3. The semiconductor device according to claim 1, wherein average vanadium concentration of the SiC substrate is 1×10¹⁷ cm⁻³ to 1×10¹⁹ cm⁻³.

4. The semiconductor device according to claim 1, wherein vanadium concentration of the first substrate is 1×10¹⁸ cm⁻³ to 1×10¹⁹ cm⁻³.

5. The semiconductor device according to claim 1, wherein the vanadium concentration of the second substrate is equivalent to the vanadium concentration of the first substrate at an interface between the first substrate and the second substrate, and is continuously reduced toward the high electron mobility transistor.

6. The semiconductor device according to claim 1, wherein a polytype of the first substrate is 4H-SiC or 6H-SiC, and
a polytype of the second substrate is 3C-SiC.

7. A method for manufacturing the semiconductor device according to claim 1, wherein the second substrate is manufactured by a CVD method.
